(19) United States
(12) Patent Application Publication
(10) Pub. No.: US 2026/0342107 A1
(43) Pub. Date: Oct. 29, 2026

(54) Device and Method for Monitoring and Levelling the Charge Level of Batteries

(71) Applicant: Vladimir GORJUNOW, Zurich (CH)

(72) Inventors: Nikolay Alekseevich DEGTJAREV, Tula (RU); Yuri Alexandrovich SIZOV, Moskau (RU)

(21) Appl. No.: 19/099,775

(22) PCT Filed: Aug. 16, 2023
(86) PCT No.: PCT/IB2023/058213

§ 371 Date: Jan. 30, 2025

(30) Foreign Application Priority Data
Aug. 16, 2022 (RU) 2022122186
Aug. 16, 2022 (RU) 2022122187

(51) Int. Cl. H02J 7/56; G01R 31/36; G01R 31/3842; H01M 10/44; H01M 10/46; H02J 7/80

(52) U.S. Cl. CPC H02J 7/56; G01R 31/3646; G01R 31/3842; H01M 10/441; H01M 10/46; H02J 7/80

(57) ABSTRACT

The invention relates to the field of electrical engineering. The invention can be used in devices installed in a vehicle. The aim of the invention is to expand the functionality of the device. Extension through timely diagnostic control. As well as an extension by adapting the battery pack to a more comprehensive set of electrical parameters. The monitoring device and method comprise a battery set (100) (Battery).

The invention relates to the field of electrical engineering. The invention can be used in devices designed for continuous automatic monitoring. These devices are also designed for balancing the state of charge of parallel-series connected batteries in a block. This block is installed in the vehicle, for example in a hybrid car or an electric car.

A signaling system according to WO 2000005596 and US20170077559 is known from the state of the art. Here, a device and a method for controlling batteries connected in parallel series are presented. The batteries are equipped with a separate power supply, a microcontroller and a signal transmission system for each horizontal row.

A battery power source device and a method for determining the current for it according to a patent (EP1317045, priority from 27.11.2002, published on 07.10.2009) are also known from the state of the art. This is necessary to control and balance the current in the vertical rows of battery blocks when they are connected in parallel-series in the block. In this unit, expensive current sensors are required to measure the current consumption in each vertical row.

A common disadvantage of these analogs is the lack of simultaneous control and equalization of voltage and current.

The closest to the proposed invention in terms of technical essence are the device and method for monitoring and leveling the state of charge of the batteries of the battery set according to RU 2695646. The device contains:
a power supply in the form of a battery pack (BA) with batteries connected in parallel series. In the power source, each battery of the battery pack (BA) is equipped with a resistor with an equally small value R. With one of the wires, the resistor is electrically connected to the positive contact of each battery. The parallel connection of the batteries in the battery pack (BA) for each horizontal row of m batteries is done by combining the second terminals of the resistors to a common terminal of the horizontal row of the battery pack. In this case, the number of horizontal rows is equal to n. The vertical rows are formed by connecting the anode of the previous battery in series with the cathode of the next in each horizontal row. In vertical rows, m vertical rows with a total number of n batteries in the block m\n are formed by series connection.

The device also includes:
consumption and charging mode system with consumption current sensor;
switching control device;
battery switching unit:—two buses a and b for measuring electrical parameters;
output from the common cable of the h-th row of the battery pack (BA);
microcontroller;
digital indicators for batteries that are problematic in terms of electrical parameters.

The disadvantages of the prototype include:
the inability to measure and balance the asymmetry of currents in the vertical rows of the block. These blockages noticeably affect the state of charge of the batteries and their lifespan. Such an influence occurs when connecting them in a horizontal row via small resistors. When the electrical parameters of individual batteries are not equal;
Lack of possibility for continuous control. The absence of the ability to balance the state of charge of each individual battery in the block.
Leveling for Current, Voltage, Resistance and Differential Current Consumption.

The aim of the invention is to expand the functionality of the device. Extensions through timely diagnostic control. The task of the present invention is also to align the block of parallel-series connected batteries. In accordance with a more comprehensive set of electrical parameters. This increases the lifespan and safety of the battery pack. It also reduces energy consumption during device operation and manufacturing costs.

The technical result is as follows:
1. The proposed device and monitoring method performs the following functions:
Control of a complex of electrical parameters of each battery. The monitoring enables early diagnosis and identification of problematic batteries. The reset is not only due to the imbalance of voltages in the horizontal rows. But and additionally to the imbalance of currents in vertical rows. And also due to the imbalance of internal resistances and different current consumption of the batteries during overcharging and low charge.

Display on the block of the digital indicator of the serial numbers of the row with problematic voltage. Also additionally display problematic batteries in a horizontal row. And on the screen to display a bitmap image with two coordinates. Display with modulation of brightness by the amplitude value of the differential current consumption of the batteries. When the number of pixels corresponds to the number of batteries in the battery pack.

Use of the control results for a series of electrical parameters. Use for individual alignment of problematic block batteries.

The state of charge balancing is done for each problematic battery proportional to the degree of voltage inequality. The state of charge balancing is additionally done according to the imbalance of currents, internal resistance and different power consumption. The alignment is done during recharging. The balancing is also done at weak charge taking into account the current consumption of the battery pack.

Active and passive voltage balancing is performed in horizontal rows. Alignment and additional currents in the vertical rows of block batteries are carried out. The implementation is done with intensive active equalization by pulse currents with adjustable value greater than one ampere at an efficiency of over 90%.

The technical result is achieved by the fact that the device and method for monitoring and balancing the state of charge of the batteries of the block (battery) contains:
power supply. Power supply in the form of a block of parallel series-connected batteries. Power supply connected to the consumption and charging mode system, to the consumption current sensor. Power supply connected to the switching unit of horizontal battery rows, controlled by the battery switching control unit.
common buses a and b for measuring electrical parameters;
common terminal of the h-th horizontal row for voltage balancing;
digital display unit;
microcontroller

At the same time, each battery of the block is equipped with a resistor with the same small value R. At one end, the resistor is electrically connected to the positive terminal of its battery. The second terminals of the resistors are combined into a common terminal and form n horizontal rows. Vertical rows are formed by connecting the anode of each previous battery in series with the cathode of the next.

According to the invention, the difference is that the proposed device or method has:
additionally equipped with a switching unit for current keys 103 (BKT) from vertical battery rows with a total of m. Each input is connected to the electrical output of the anode of its battery in the n-th horizontal row of the battery pack. The outputs of the current switches of the block with odd serial numbers are combined into a common output. The outputs of the current switches of the block with odd serial numbers are connected to a common bus j. Outputs of current switches with even serial numbers of the block are combined into a common output. The outputs of the current switches with even serial numbers are connected to a common bus g;
switching unit for current keys with 10 vertical battery rows is additionally equipped with a control unit for switching control devices for current keys with 120 vertical rows (BUKT). The block is based on a demultiplexer with the number of outputs m. Accordingly, the input frequency controlled by the polling cycle is at least m times the polling frequency f of the horizontal rows of the battery pack from the microcontroller. And at the output with m outputs connected to the switching unit of the current switches of vertical rows. Connection with the possibility of sequential supply of the control devices of m current switches of the specified unit with supply voltage. At the same time, a series connection of devices is provided;
voltage measurement and balancing unit 300 (BIVN) contains: a rectifier 301 (V), a pulse matching amplifier 302 (US), a limiting resistor (R303) and is additionally equipped with a voltage divider on two resistors (R301, R302). In this case, the rectifier 301 (B) of the device contains a pulse transformer with a primary and a secondary winding, as well as a full-wave rectifier. In addition, the primary winding of the transformer is connected to common buses for measuring electrical parameters a and b. A secondary winding to the input of a full-wave rectifier. The load of the rectifier is a voltage divider across two resistors (R301, R302).

The output of the rectifier is connected to the input of the pulse; matching amplifier 302 (US). The output of the rectifier is connected via the limiting resistor R303 to the common output of the horizontal row of the battery pack with serial number h. A pulse output matching amplifier 302 (US) and the midpoint of the voltage divider, which is connected to the microcontroller 600 (MK);
additionally equipped with a current measurement and leveling unit 400 (BIVT). The unit contains a rectifier 401 (V), a pulse matching amplifier 402 (US), four normally open single-position switches 403, 404, 407, 411 (KI1, KI2, KI3, KI4), pulse inversion 405 (UI) and non-inverting voltage amplifiers 410 (UN), comparator 406 (K), voltage-controlled converter 408 (DC/DC), low-voltage electronics power supply 409 (BPN) and limiting resistor (R401). In this case, the rectifier 401 (B) contains a pulse transformer with two primary and one secondary winding, as well as a full-wave rectifier. In addition, the primary windings of the transformer are connected oppositely to the common buses j g. A center tap of the primary winding of the transformer is connected to the signal ground.

The output of the rectifier 401 (B) is connected to the input of the pulse matching amplifier 402 (US). And its output is connected to the microcontroller 600(MK). The first two keys are connected by input to the output of the rectifier 401 (B). These are normally open single-position switches. The key closure is controlled by the 600(MK) microcontroller. And the outputs of the keys are connected to the inputs of the pulse inverting 405 (UI) and non-inverting 410 (UN) pulse voltage amplifiers. The inverting and non-inverting voltage pulse amplifiers are connected by input to the inputs of the first two switches. A at the output with the first input of the comparator 406(K). The comparator is connected via the first input to the outputs of the inverting and non-inverting voltage pulse amplifiers. Via the second input A is connected to the microcontroller. The output of the comparator is connected to the control device for closing the third single-position normally closed switch 407 (CL3). The third single-position normally closed switch is connected via the input to a voltage-controlled converter. The key closure is controlled by a comparator. A is connected at the output via the limiting resistor R401 to the rectifier 401 (B). The voltage-controlled converter 408 (DC/DC) is connected by input to the low-voltage electronics power supply 409 (LPV). The converter voltage is controlled by a microcontroller. At the output, the converter is connected to the third and fourth single-position normally closed switches. The fourth single-position normally closed switch 411 (KI4) is connected by input to a voltage-controlled converter 408 (DC/DC). The key closure is controlled by a microcontroller. A at the output, the key is connected via a limiting resistor R401 to a rectifier 401 (B);
microcontroller 600 (MK) is configured to:

Set the required clock frequency for polling the switching control unit of the control devices of the current switches of the vertical rows. Set the frequency at least m times higher than the frequency f of polling the horizontal rows of the battery pack.

Receive measurement information from the voltage measurement and balancing unit and the current measurement and balancing unit;
Determine programmatically the average values of voltage and current pulses and their deviations from the average values. Determine programmatically, taking into account the sign, the maximum deviation from the average value of the asymmetry voltage of the horizontal rows and the current of the vertical rows;
Calculate the Differential Current Consumption.
Generate and transmit programmatically controlled action to balance the current in vertical rows;
Programmatically generate and transmit, taking into account the maximum value and sign of the unbalance voltage in horizontal rows and the unbalance current in vertical rows. Also current consumption and charging;
Perform programmatically additional control measures by aligning the current in vertical rows. In the presence of both positive and negative asymmetry in the horizontal rows with priority of the positive sign of the asymmetry voltage in the horizontal rows;
programmatically additionally with a predetermined frequency to transfer the device and method to measurement mode. Transfer by opening the first and second keys, closing the fourth key and applying a reference blocking voltage from the output of the microcontroller to the input of the comparator;
Generate programmatically an emergency shutdown command for the device. Generate in case of inadmissible deviations of the controlled parameters from the specified values;
additionally process programmatically the measurement information on voltage, current and differential current consumption and transmit to the digital display unit;
The digital display unit 700 (DIC) contains a digital display of the serial numbers of batteries that are problematic in terms of electrical parameters. This unit is additionally equipped with a two-coordinate raster screen. This screen has the same number of pixels as the number of batteries in the battery pack. Pixels to represent the relative change in current consumption as luma modulation. By the amplitude of this parameter when polling horizontal and vertical battery rows. In addition, each of the listed display devices is controlled by a microcontroller.

Another difference is also that the limiting resistors of the voltage measurement and balancing units as well as the current measurement and balancing units are simultaneously fuses. Resistors with small value R additionally consist structurally of a material with high specific electrical resistance. They consist of segments of a resistance band that are electrically connected between the welding points of adjacent anodes and cathodes of vertical battery rows. The sections of the resistance band are electrically connected by welding to the jumpers of the vertical rows. The segments are structurally identical. The bridges of the vertical rows are electrically connected to the poles of adjacent batteries of the vertical rows.

The proposed invention is explained in more detail using the attached drawings.

They show:

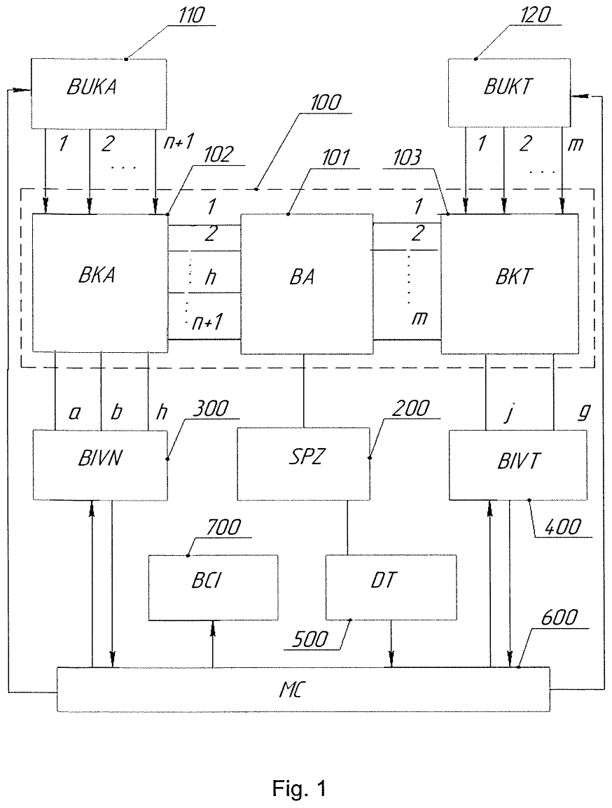

FIG. 1 a functional diagram of a device for monitoring and balancing the state of charge of the batteries of the block (battery);

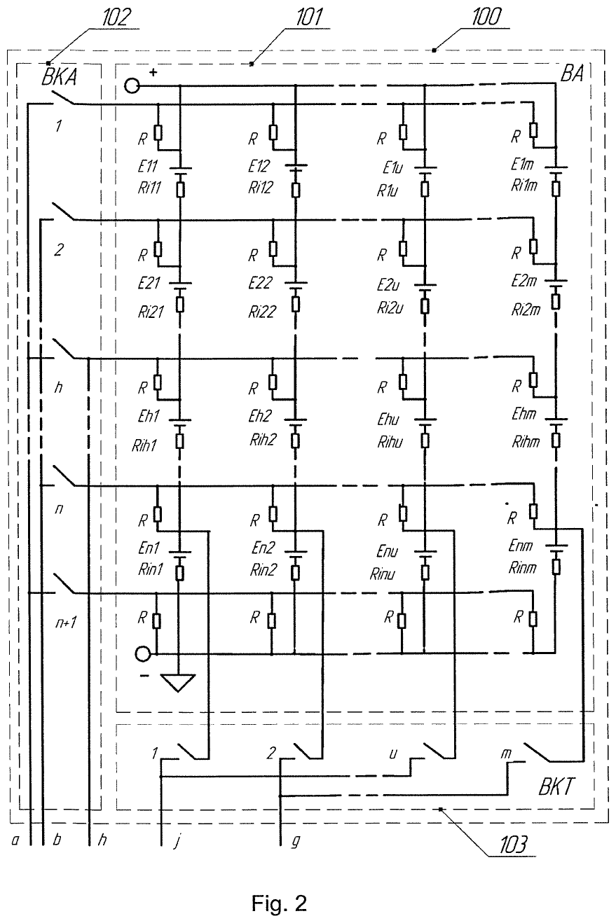

FIG. 2 a functional diagram of the battery switching block (batteries);

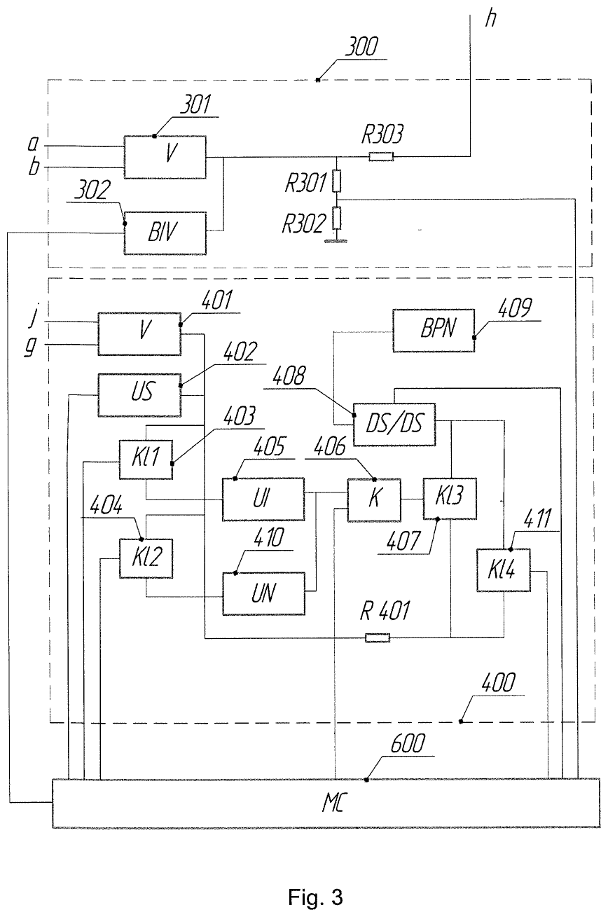

FIG. 3 a functional diagram of blocks for measuring and balancing voltages and currents;

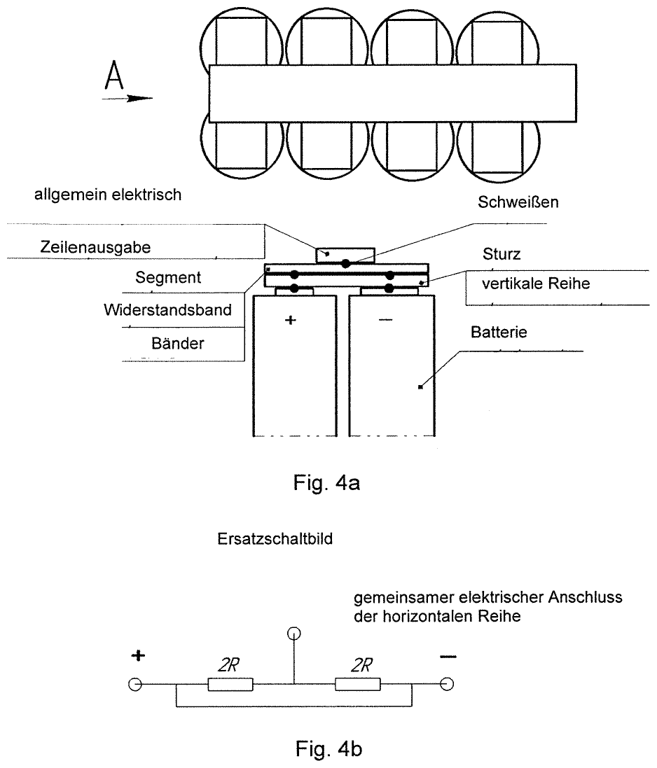

FIG. 4a the design of the installation of the horizontal rows of the battery pack with a resistance band;

FIG. 4b a replacement circuit;

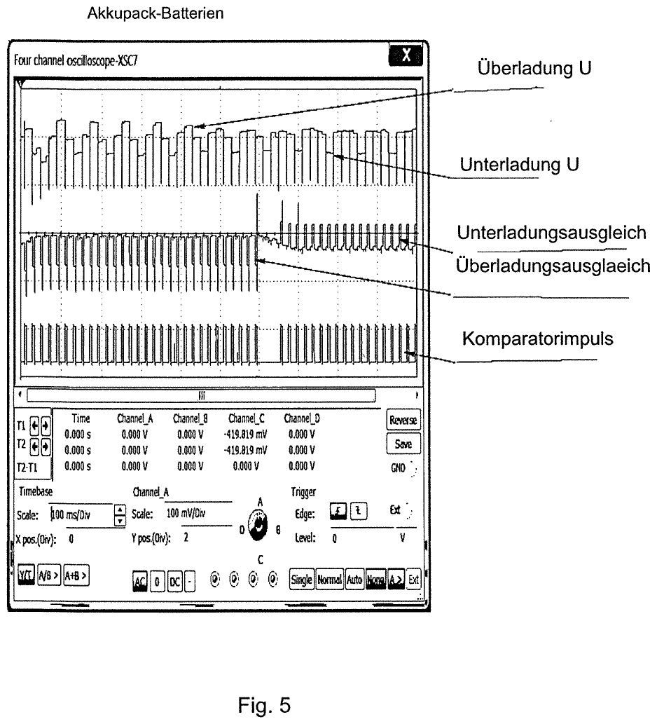

FIG. 5 an oscillogram of current balancing.

Leveling during charging with transition to leveling at weak charge in vertical rows.

The monitoring device and method according to the proposed invention (FIG. 1) includes:
Battery pack 100 (Battery)). Block 100 (Battery) contains a battery set 101 (BA). Block 100 (Battery) consists of batteries connected in parallel series, Block 100 (Battery) contains a battery switching unit 102 (BKA). Unit 100 (Battery) is additionally equipped with a switching unit for current keys 103 (BKT);
Battery switching control device 110 (BUKA);
additionally control unit for switching current switches of vertical rows 120 (BUKT);
Consumption and charging system 200 (SDR);
additionally block for measuring and balancing voltage 300 (BIVN);
additionally block for measuring and leveling current 400 400 (BIVT);
Current sensor 500 (DT);
Microcontroller 600 600 (MK);
Digital display block 700 (BCI);
common rows a and b, measuring the voltage of horizontal battery rows 101 (BA);
General output of the horizontal row of the battery pack 101 (BA) with serial number h;
additionally rows J and G of the key outputs with odd and even serial numbers of unit 103 (BKT) for measuring voltage proportional to the current of vertical odd and even rows of batteries 101 (BA).

In this case, the interaction of the listed blocks in the static part of the description is as follows.

In block 101 (BA) (FIG. 2), each battery is represented by a current source with voltage E and internal resistance Ri. Each battery is equipped with an equally small resistance R. At one end, the resistance R is electrically connected to the positive terminal of its battery. The second terminals of each resistor are combined into a common terminal of a horizontal battery row, in this case n horizontal rows with m batteries each with a total number of batteries in block 101 (BA) n\m.

The number of common outputs of horizontal rows is n+1. In addition, n+1 common conclusions are formed by m combined resistors of equally small value R with the negative pole of block 101 (BA). The pole of the block is the signal ground.

In this case, the value of the numerical value of resistors with small value R is selected depending on the variation of the nominal value of the battery voltage and the internal resistance of the battery, which is acceptable for the battery type used and does not exceed 1 ohm.

The vertical rows are formed by connecting the anode of each previous battery in series with the cathode of the next. Verticals are formed by series connection m vertical rows.

The battery set 101 (BA) is additionally equipped with an electrical output from the anode of each battery in the nth horizontal row. Via this output, it is connected to the input of its key in the current switch switching unit 103 (BKT).

The horizontal battery row 102 (BKA) contains a set of keys with low internal resistance totaling n+1. Each key is connected via an input to the common output of its horizontal battery row. A-output keys of block 102 (BKA) with odd serial numbers are combined into a common output. The keys of block 102 (BKA) with odd serial numbers are connected to a common bus a. The outputs of the keys with even serial numbers of block 102 (BKA) are combined into a common output. The outputs of keys with even serial numbers are connected to a common bus b.

The switching unit of the horizontal battery rows 102 (BKA) is also equipped with a common output of the horizontal battery row 101 (BA) with serial number h. The block for batteries 101 (BA) corresponds to a voltage of U\h. Here, U is the average voltage value across the horizontal battery row. This value is close to the nominal value of the voltage E of each of the batteries in block 101 (BA).

The battery pack 101 (BA) (FIG. 2) is additionally equipped with a switching unit for current switches 103 (BKT). The block contains a series of controlled single-position normally open switches, keys with low internal resistance totaling m. Each of the keys is connected at the input to the electrical output of the anode of its battery in the nth horizontal row of the battery block 101 (BA).

At the output, the keys of block 103 (BKT) with odd serial numbers are combined into one output. Block keys with odd serial numbers are connected to a common bus j.

The outputs of keys with even serial numbers of the BKT block (103) are combined into one output. The outputs of keys with even serial numbers are connected to a common bus g.

The battery switching control unit 110 (BUKA) (FIG. 1) allows the pairwise connection of two adjacent keys of odd and even horizontal rows of the battery pack 101 (BA) and a connection to common buses for measuring electrical parameters a and b with a serial polling rate f.

The switching unit current keys 103 (BKT) is equipped with a control unit for switching the current keys 120 (BUKT). This block is based on a demultiplexer with the number of outputs m. The demultiplexer serially supplies the control devices of the m keys of the current key switching unit 103 (BKT) with supply voltage. The demultiplexer ensures the closing of the keys at a polling frequency of the current switches that is not less than m times the frequency f of the key polling of block 110 (BUKA).

The consumption and charging system 200 (SDR) is connected between the positive and negative poles of the battery pack 101 (BA).

The voltage measurement and balancing unit 300 (BIVN) contains a rectifier 301 (V), a pulse matching amplifier 302 (US), a voltage divider on two resistors (R301), (R302) and a limiting resistor (R303). In this case, the rectifier 301 (B) consists of a pulse transformer with a primary and a secondary winding. The 301 rectifier (B) consists of a full-wave rectifier. The primary winding of the transformer is connected to common buses for measuring electrical parameters a and b. The rectifier load is an additionally introduced voltage divider on two resistors (R301), (R302). The output of the rectifier 301 (V) is connected to the input of the pulse matching amplifier 302 (US). Via a limiting resistor (R303), the output of the rectifier is connected to the common output of the horizontal row of the battery pack 101 (BA) with serial number h. The output of the pulse matching amplifier 302 (US) and the midpoint of the voltage divider are connected to the microcontroller 600 (MC).

The monitoring device and method according to the proposed invention is additionally equipped with a current measurement and balancing unit 400 (CUBT) (FIGS. 1, 3). This block contains:
Rectifier 401 (B);
Pulse matching amplifier 402 (US);
Controlled single-position normally open switches 403 (KI1) and 404 (KI2) (hereinafter referred to as keys);
Voltage inverting amplifier 405 (UI);
Comparator 406 (K), key 407 (KI3);
Voltage-controlled converter 408 (DC/DC);
Power supply for low-voltage electronics 409 (BPN);
Non-inverting voltage amplifier 410 (UN);
Key 411 (CI4);
Limiting resistor (R 401).

In this case, the rectifier 401 (B) is equipped with a pulse transformer with two primary and one secondary winding. The primary windings are connected oppositely to the common buses j and g of the voltage measurement. Proportional to the current vertical odd and even rows of batteries 101 (BA), outputs of keys with odd and even serial numbers of block 103 (BKT) are connected. The center tap of the primary winding is connected to the signal ground.

A secondary winding is connected to a full-wave rectifier 401(B). The output of the rectifier is connected to the input of the pulse matching amplifier 402 (US) to the keys 403 (CI1) and 404 (CI2). Via a limiting resistor (R 401) it is connected to the output of the keys 407 (CI3) and 411 (CI4). The output of key 403 (CL1) is connected to the input of the inverting voltage amplifier 405 (UI). The output of key 404 (CL2) is connected to the input of a non-inverting voltage amplifier 410 (UN). The outputs of the inverting voltage amplifier 405 (UI) and the non-inverting voltage amplifier 410 (UN) are connected to the first input of the comparator 406 (K). The reference voltage controlled by the microcontroller 600 (MK) is supplied to the second input of the comparator. The output of the comparator 406 (K) controls the closing of key 407 (CL3).

The input of keys 407 (KI3) and 411 (KI4) is supplied with the voltage of converter 408 (DC/DC) controlled by microcontroller 600(MK). The input of converter 408 (DC/DC) is connected to the output of the low-voltage electronics power supply 409 (LPV). By closing keys 403 (KI1), 404 (KI2) and 411 (KI4), control devices are connected to microcontroller 600 (MK).

The current sensor 500 (DT) is designed to measure the current consumption in the charge consumption system 200 (SDR) and process the measurement results in the microcontroller 600 (MK).

The microcontroller 600 (MK) is electrically connected to the following blocks:
blocks 110 (BUKA) and 120 (BUKT) to provide polling clock pulses;
block 300 (BIVN) to receive measurement information on voltage;
block 400 (BIVT) to receive measurement information on current and to control voltage as well as current and control for closing keys 403 (CI1) and 404 (CI2) and 411 (CI4);
current sensor 500 (DT) to receive measurement information on current;
digital display block 700 (BCI). The connection is for digital display of the serial numbers of the batteries of BA unit (101) that are problematic in terms of electrical parameters, problematic in terms of displaying a bitmap on a two-coordinate display.

The Proposed device and monitoring method work in the following way.
The workflow for monitoring and aligning the electrical parameters of Block 100 (Battery) in measurement mode and active alignment.
In measurement mode, keys 403 (CL1) and 404 (CL2) are open. A high blocking voltage is applied to the second input of comparator 406 (K) at microcontroller 600 (MK). A voltage at voltage-controlled converter 408 (DC/DC) is set equal to the DC voltage at the output of rectifier 301 (V). In this case, key 411 (KI4) is closed.

Through the signal of the microcontroller 600 (MK), inputs are applied to the input of the dual demultiplexer control device for switching batteries 110 (BUKA) (FIG. 1) with the number of outputs n+1. When closing pairs of keys with low internal resistance, the switching unit consists of horizontal battery rows 102 (BKA). With a frequency f of the switching control unit 110 (BUKA) on common buses a and b for measuring electrical parameters, positive and negative rectangular voltage pulses alternate with an amplitude. The amplitude is proportional to the voltage on each of the horizontal rows of block 101 (BA) (FIG. 2). At the common buses A and B, these pulses are fed to the input of the voltage measurement and balancing unit 300 (BIVN).

In block 300 (BIVN) (FIG. 3), the average value of the constant voltage across all horizontal battery rows is formed at the output of rectifier 301 (B). The rectifier is designed for full-wave rectification. The generated value at a given transformation ratio and in the absence of asymmetry of the horizontal rows is equal in magnitude to the voltage at the output of the horizontal row of the BA battery set (101) with serial number h.

If the amplitude of the error voltage on one of the horizontal battery rows differs, rectangular voltage pulses from the mean value (V) to the mean value of the DC voltage are superimposed at the output of rectifier 301. The amplitude of the rectangular voltage pulses is proportional to the magnitude of the asymmetry voltage of the problematic horizontal row (FIG. 5). In addition, the positive value of the asymmetry voltage pulse corresponds to overcharging.

For each series connection of a horizontal row, the anodes of the batteries of the n-th horizontal row are connected with keys with low internal resistance with odd serial numbers (FIG. 2) to a common bus j. Keys with even serial numbers, connection to a common bus, measurement of voltage proportional to the current of the vertical odd and even rows of batteries of block 101 (BA). When switched on by a signal from the microcontroller 600 (MK) with a frequency fm, which is m times the polling frequency of the common rows a and b of the horizontal rows, the control unit switches the control devices of the current switches of the vertical rows 120 (BUKT), the switching unit for the current switches of the vertical rows 103 (BKT).

When voltage from the common buses J and G is applied to the oppositely connected primary windings of the pulse transformer of rectifier 401 (V), the average value of the constant voltage across all vertical battery rows is formed. The value is equal to the voltage at the output of the voltage-controlled converter 408 (DC/DC) at a given transformation ratio without significant asymmetry of the vertical rows. The value of the converter is set equal to the constant component at the output of the rectifier unit for measuring and balancing voltage 300 (BIVN). The rectifier transformer 401 (B) is produced according to the full-wave rectification scheme at the output of rectifier 401 (B) after rectification.

If the amplitude of the error voltage on one of the vertical battery rows deviates from the average value, rectangular voltage pulses are formed at the output of rectifier 401 (B) (FIG. 5). The voltage amplitude is proportional to the magnitude of the mismatch voltage of the problematic vertical current row. In addition, the positive value of the mismatch voltage pulse corresponds to a weak charge. A negative value corresponds to the charging of the controlled vertical battery row of block 101 (BA).

In the claimed device for transformers, rectifiers 301 (B) and 401 (B) set the same transformation ratios. At the same time, for the measurement units voltage balancing, current measurement and balancing, the constant voltage components at the outputs of their rectifiers are equal.

The microcontroller 600 (MK) controls the value of the reference voltage at the input of comparator 406 (K) to the maximum amplitude of the error pulses relative to the average value at the output of rectifier 401 (B).

The results of measuring the average voltage value, the asymmetry relative to the average value and its magnitude in terms of voltage, current and calculated differential current consumption in blocks 300 (BIVN) and 400 (BIVT) are transmitted by microcontroller 600 (MK). The results are passed on to the voltage and current balancing control. They are also transmitted for display to the digital display block 700 (DDI).

In block 700 (BCI) on a digital indicator, the following is performed:
digital display of the serial number of the row with a problem voltage;
the serial number of the problematic battery in the horizontal row;
display of a two-coordinate display of a bitmap image vertically and horizontally on the screen. Display with brightness modulation of the battery coordinates by the amplitude value of the differential current consumption. The number of pixels corresponds to the number of batteries in the battery pack 100 (BA).

In measurement mode, simultaneously with measuring the amplitude of the voltage imbalance of the horizontal rows from the constant voltage of the common output of the horizontal row of the battery pack 101 (BA) with serial number h. An active balancing of the error voltage of the problematic horizontal rows takes place, active balancing occurs both during overcharging and weak charging. The balancing is done via the limiting resistor (R303) and the rectifier 301 (B).

Also in measurement mode, simultaneously with measuring the amplitude of the asymmetry of the currents of the vertical rows from the constant voltage of the voltage-controlled converter 408 (DC/DC), the asymmetry currents of the problematic vertical rows are actively balanced. Active balancing occurs both during overcharging and weak charging. The active balancing is done via a closed key 411 (KI4), a limiting resistor (R401) and a rectifier 401 (B).

In this case, the magnitude of the balancing currents does not exceed hundreds of milliamperes. However, with a slight imbalance in current, the effect of such balancing is noticeably felt.

The workflow for intensive active balancing of the electrical parameters of Block 100 (Battery).

Key (KI1) in the horizontal rows and key 411 (KI4) open. This happens when the value exceeds the threshold set at microcontroller 600 (MK). Negative pulses of asymmetry of the vertical rows are received from rectifier 401 (V) to the voltage inverting amplifier 405 (UI) (FIG. 5). The amplitude of these pulses is proportional to the overcharge current. After inversion and amplification at the inverting voltage amplifier 405 (UI), amplified positive pulses are fed to the input of comparator 406 (K).

Based on the measurement results, the second input of comparator 406 (K) is supplied with a positive reference voltage from microcontroller 600 (MK). The voltage is proportional to the maximum amplitude of current asymmetry. The voltage is slightly lower than the maximum amplitude of the amplified pulses of the imbalance of currents of the vertical rows. This activates comparator 406 (K) and starts the process of intensive active current leveling (FIG. 5).

At the same time, microcontroller 600 (MK) sets a voltage at the output of voltage-controlled converter 408 (DC/DC) that is lower than the initial average value.

When comparator 406 (K) is pulsed, negative pulses are generated via key 407 (KI3). Due to the reduced relative initial average voltage of converter 408 (DC/DC) at the output of key 407 (CL3), pulses are formed. Negative pulses are fed via the limiting resistor (R401) to the secondary winding of the 401 rectifier pulse transformer (V). And through the primary winding and buses j and g measuring the voltage proportional to the current of the vertical battery rows 101 (BA), the alignment of the problematic vertical row current is carried out (FIG. 5).

The pulse transformer of rectifier 401 (B) is used in this case as a reversible element. In this element, rectangular voltage pulses with measurement information are transferred from the primary to the secondary winding. From the secondary winding, balancing control pulses are transferred to the primary winding.

As the current flow increases, the voltage at the anode decreases. The increased current flows in the problematic vertical row. The increased current is caused by overcharging due to the increased voltage drop across the internal resistance Ri of the corresponding battery in the nth horizontal row (FIG. 2). This appears at the output of rectifier 401 (B) as a negative voltage pulse (FIG. 5).

During current balancing, the output of rectifier 401 (V) is amplified with a significantly amplified negative current balancing voltage pulse.

An even larger voltage drop occurs across the internal resistance Ri of the corresponding battery in the nth horizontal row (FIG. 2). This reduces the total voltage of the vertical problem row. This leads to a corresponding reduction in current in the problematic vertical row and ensures its balancing. In this case, there is also a partial balancing of the voltage imbalance in the horizontal rows.

When the battery charging voltage equalizes, the comparator may stop working and the monitoring device and monitoring method switch to measurement mode. And if at the same time significant imbalance voltages occur in the horizontal rows, voltage balancing of the horizontal battery rows occurs during weak charging (FIG. 5).

This cycle is repeated until the asymmetry voltage in the horizontal and vertical rows is below the set threshold. This also reduces the voltage. The voltage is supplied from the output of a voltage-controlled converter 408 (DC/DC). Proportional to the maximum voltage asymmetry in the horizontal rows.

Additionally, the microcontroller 600 (MK) switches the device and monitoring method to measurement mode under program control by opening keys 403 (CL1) and 404 (CL2) at a set interval. Priority is always given to the presence of significant positive imbalance pulses of the horizontal rows during charging. So if at the same time negative mismatch pulses with significant amplitude are also received at the input of microcontroller 600 (MK), only key 403 (CI1) remains closed. And only when the positive mismatch pulses fall below the threshold significance level in amplitude does key 403 (CL1) open.

The maximum positive rectangular error voltage at the output of rectifier 301 (B) (FIG. 5) may be below the set threshold. However, significant negative pulses corresponding to a weak charge may occur. The operating frequency of the device can be repeated.

This closes key 404 (CL2) and opens key 403 (CL1). Rectifier 401 (V) receives non-inverting voltage amplifier 410 (UN) receives positive pulses of asymmetry of the vertical rows. After amplification, amplified positive pulses are input to comparator 406 (K).

Additionally, current balancing during weak charging (FIG. 5) occurs in the same way as during overcharging. But only in this case, converter 408 (DC/DC) supplies a positive voltage. Voltage proportional to the maximum asymmetry of the horizontal rows with weak charge, positive balancing pulses. For this reason, current balancing with a weak charge involves positive pulses with increased strength (FIG. 5).

If there are no significant positive and negative mismatch pulses in the horizontal rows, both keys 403 (CL1) and 404 (CL2) open, key 411 (CL4) closes. A voltage-controlled converter 408 (DC/DC) is supplied with a voltage equal to the voltage of the DC component at the output of rectifier 301 (V). Both the device and the monitoring method switch to measurement mode. This also performs active alignment with a weak current through a closed key 411 (CI4) from converter 408 (DC/DC). The combination when both keys 403 (KI1) and 404 (KI2) are closed simultaneously is invalid.

Thereby voltage balancing in horizontal rows and current balancing in vertical rows occurs through:
continuous passive balancing through small resistors R;
continuous active voltage balancing through pulses of frequency f of the asymmetry voltage of the horizontal rows. From the common output of the horizontal row of the battery pack with serial number h, both during overcharging and weak charging;
active current balancing in vertical row measurement mode. Alignment through pulses with a frequency at least m times higher than the polling frequency f of the horizontal rows of the battery pack. From a voltage-controlled converter 408 (DC/DC) both during overcharging and undercharging;
current leveling, in intensive active leveling mode in vertical rows. Balancing through pulses with a frequency at least m times higher than the polling frequency f of the horizontal rows of the battery pack from a voltage-controlled converter 408 (DC/DC). Balancing both during overcharging and weak charging with currents up to several amperes.

The main effect of active leveling in this mode is achieved by the following:
The n-th horizontal rows must be selected more carefully. Select according to the same voltage E and the same internal resistance Ri. As they are reference for this series.
Also, the limiting resistors of the measurement, voltage balancing, current measurement and balancing units are fuses.

To save costs, the resistors with small R (FIG. 2) are structurally made of a material with high specific electrical resistance. Manufactured in the form of segments of a resistance band. On one side, it is electrically connected by welding to the bridges of the vertical rows and structurally identical (FIG. 4a). And on the other side, the parts of the resistance band are electrically connected by welding to a common outlet of the horizontal row. The bridges of the vertical rows are electrically connected to the poles of adjacent batteries of the vertical rows. (FIG. 4b).

Segments of resistance band are electrically connected by welding to jumpers of vertical rows. The segments repeat the configuration. The bridges of the vertical rows are electrically connected to the poles of adjacent batteries of the vertical rows.

The common electrical output of the horizontal row is installed perpendicular to the band segments. A common outlet is electrically connected to the midpoints of each band segment. Connecting a common electrical output of a horizontal row in the middle of a band piece provides a common electrical resistance. The electrical resistance between the anode of each battery (FIG. 4b) and the common output of the horizontal row is R.

The implementation of the device according to the proposed invention in the power plants of hybrid vehicles and electric vehicles will allow:
Increase the lifespan of the battery block. Increase performance through monitoring and balancing of current, voltage, internal resistance and different current consumption for each problematic battery. While simultaneously balancing overcharged and weakly charged batteries. Increase lifespan in continuous operation in charging and current consumption mode.
Improve the safety of the battery pack. Improve safety by monitoring and balancing current, voltage, resistance and different current consumption in each of the batteries in this device. Improve safety by detecting batteries with excessive differential current consumption, which leads to overheating, almost immediately.
Provide good visibility when displaying batteries that are problematic in terms of different energy consumption and lead to overheating. Obtain high clarity when displayed on a two-coordinate display. With high visibility with modulation of brightness by the amplitude value of the relative change in current consumption.
Reduce energy consumption during device operation and manufacturing costs in the present invention. Reduce energy costs by putting the main energy of active leveling into current leveling in vertical rows. A use active voltage balancing in horizontal rows as an auxiliary means.
The circuit solution used in the claimed device allows for significant savings in the cost of electronic devices. As inexpensive keys can be used for voltage balancing. Keys with relatively high internal resistance. A use current balancing switches with low internal resistance. However, with low operating voltage and without high voltage decoupling.

Since the number of horizontal rows is many times greater than the number of vertical rows, the economic effect can be significant. In this case, the main effect of active balancing is achieved by the current in vertical rows. Voltage balancing in each horizontal row is mainly done by passive balancing. Leveling through small resistors and active leveling for voltage and current.

The proposed methods make it possible to control and balance the state of charge of the batteries of block 100 (Batteries) in terms of current and voltage.

The proposed method is carried out as follows:
The battery switching unit 102 (BKA) performs the switching of n+1 common terminals of the horizontal rows. Rows with odd serial numbers with bus a for measuring electrical parameters. A even rows with electrical measurement bus b;
The common terminal n+1 of the horizontal battery row Block 101 (BA) (FIG. 2) is connected to the negative pole of Block 101 (BA). Block 101 (BA) is a signal ground via m resistors with the same small value R. In this case, the value of the numerical value of the resistors with small value R is selected depending on the spread of the nominal voltage of the batteries and the internal resistance of the battery, which is acceptable for the battery type used;
Switching unit of the current switches of the vertical rows 103 (BKT) (FIG. 2) performs the switching of m electrical lines from the anodes of the batteries of the n-th horizontal row of the battery unit 101 (BA) with odd serial numbers with bus j. A with even sequence numbers with bus g;
The control unit switches the horizontal battery rows 110 (BUKA) (FIG. 1) in pairs with the supply voltage. Applying voltage to the control devices of two adjacent keys of odd and even horizontal rows of the battery switching unit 102 (BKA), thereby closing them;
Control unit for switching control devices of current switches of vertical rows 120 (BUKT) with the number of outputs m, supplying supply voltage.
Unit for measuring and balancing voltage 300 (BIVN) (FIG. 3) receives the variable component of the voltage at the output of rectifier 301 (B). Is obtained from rectangular voltage pulses coming via common buses a and b.
A pulse matching amplifier 302 (US) that amplifies the variable component proportional to the magnitude of the voltage imbalance of the horizontal rows of the battery pack 101 (BA);
Obtain a constant voltage component from the output of an additionally introduced voltage divider on resistors R 301 and R 302. Transmit for measurement to microcontroller 600 (MK);
Balance the voltage of asymmetry of horizontal rows supplied from the common output of the horizontal row of battery set 101 (BA). With serial number h-value Uh through limiting resistor R 301;
Unit for measuring and balancing current 400 (BIVT) (FIG. 3) rectifies rectangular voltage pulses, voltage pulses are received on a common bus j and g. At the output of rectifier 401 (V), the DC and AC components of the voltage are obtained. And amplify the variable component proportional to the magnitude of the asymmetry of the currents of the vertical rows of battery pack 101 (BA);
With keys 403 (CL1), 404 (CL2) open and key 411 (CL.4) closed, the amplitudes of the rectangular pulses of the variable voltage component at the output of pulse matching amplifier 402 (US) are amplified. A microcontroller 600 (MK) measures the amplitude of rectangular pulses;
When key 411 (CI. 4) is open and the sign of the asymmetry pulses of the balancing voltage is positive, key 403 (CI. 1) is closed. This happens in horizontal rows to enter the intensively active mode. And with a negative sign of voltage imbalance in horizontal rows, key 404 (CI2) closes;
Compare on comparator 406 (K) alternately the amplitude of the pulses of imbalance of currents of vertical rows with the inverting and non-inverting amplifiers amplified on pulse amplifiers 405 (UI) and 410 (UN). In comparison with overcharging and undercharging, a reference voltage proportional to the amplitude of asymmetry of vertical rows is supplied from microcontroller 600 600 (MK). Control the closing of key 407 (CL3);
The current measurement and balancing unit 400 (BIVT) alternately compares on comparator 406 (K) the voltage amplitudes of the imbalance pulses of the vertical rows amplified via the inverting 405 (UI) and non-inverting 410 (UI) pulse amplifiers. With a reference voltage supplied by microcontroller 600 (MK). When the value of the reference voltage is exceeded, comparator 406 (K) is triggered;
At the output of rectifier 401 (B), compensating current asymmetry pulses are applied during active balancing in measurement mode. The pulses are supplied by a voltage-controlled microcontroller 600 (MK) converter 408 (DC/DC). They are fed via key 411 (KI4) and limiting resistor R 401 both during overcharging and weak charging;
Current consumption sensor 500 (DT) (FIG. 1) measures the current consumption in the consumption and charging system 200 (SDR). Transmission for processing of measurement results in microcontroller 600 (MK);

The microcontroller 600 (MK) performs:
Provision of clock pulses for polling the battery switching control unit 110 (BUKA) with frequency f. And the switching control unit of the control devices of the current keys of the vertical rows 120 (BUKT) with a frequency f m;
Receiving measurement information about the variable voltage component from matching amplifier 302 (US). And receiving measurement information about the constant component from the voltage divider on resistors R301 and R302. And by current from matching amplifier 402 (US) and current consumption sensor 500 (DT);
Control of the operating threshold of comparator K (406); depending on the magnitude of the asymmetry voltage in block 300 (BIVN);
Control of closing keys 403 (CI1) and 404 (CI2). Depending on the sign of the asymmetry voltage in the horizontal rows proportional to the amplitude of the asymmetry voltage in the horizontal rows;
Control of a voltage-controlled converter 408 (DC/DC). Depending on the maximum amplitude of the asymmetry voltage in the horizontal rows of block 300 (BIVN). And also depending on the asymmetry current in the vertical rows and the consumption and charging current in system 200 (SDR);
Issuing a command for emergency disconnection of the device from the circuit. Issuing a command in case of inadmissible deviations of the controlled parameters from the specified limit values;
Output of information to the digital display unit 700 (BCI);
The digital display unit 700 (BCI) displays the serial numbers of the problematic batteries in terms of voltage and current of unit 101 (BA). And also receives a bitmap with two coordinates. And an image with brightness modulation by the amplitude value of the relative change in current consumption by the number of pixels corresponding to the number of batteries in block 101 (BA).

For economic reasons, the resistors with small value R (FIG. 2) used in this method are structurally manufactured in the form of segments of a resistance band. They consist of a material with high electrical resistance (hereinafter referred to as bands). The welding points of adjacent anodes and cathodes of batteries of vertical rows are connected (FIG. 4).

The distance between the welding points for the selected material of the resistance band segment is chosen so that the electrical resistance between them is 4R. In addition, the segments of the resistance band are electrically connected by welding to the jumpers of the vertical rows and repeat their configuration.

The common outlet of the horizontal row is installed perpendicular to the band segments. A common outlet is electrically connected by welding to the middle of each band segment. And by attaching a common electrical output of a horizontal row in the middle of a resistance band segment, they provide a common electrical resistance. The resistance between the anode of each battery (FIG. 4) and the common output of the horizontal row is R.

### EXAMPLE

The experiment was conducted while simulating the operation of a fragment of the device and the method for monitoring and balancing the batteries of the battery pack. The total number of batteries connected in parallel series in the block is sixteen. Four horizontal rows with four batteries each. The batteries are connected in parallel via small resistors. The batteries are connected to the common output of the horizontal row.

Rows of four parallel-connected batteries were formed with resistors with a nominal value of 0.05 ohms. The resistors are connected with one terminal to the anode of the battery. And the other output is connected to the common output of the horizontal row.

When modeling in the MULTISIM environment, an equivalent battery replacement circuit was used. This circuit includes a power supply E. A chain of parallel-connected resistors Ri and capacitor C is connected in series with the power supply. The simulation was carried out with the numerical values of the parameters for Li-Ion 18650 batteries.

Electromechanical keys with low transition resistance were used as single-stage closing keys. The polling frequency of horizontal battery rows of the unit is 50 Hz. A vertical row −200 Hz.

Voltage balancing in horizontal rows during overcharging and undercharging was carried out by applying a balancing voltage. Supply from the common output of the horizontal row of the battery pack 101 (BA) with serial number h. Current balancing in the vertical battery rows was carried out by supplying balancing pulses from converter 407 (DC/DC).

On (FIG. 5) shows the waveforms:
[symbol] Asymmetry of electrical parameters voltage U and resistance Ri. At the output of rectifier 301 (B) during overcharging and weak charging in the horizontal rows of block 101 (BA). In the form of positive and negative deviations from the average value over a sufficiently long period of time;
[symbol] negative pulse of intensive active leveling. Current balancing at the output of rectifier 401 (V). During overcharging in the vertical rows of block 101 (BA). After alignment by overcharging in the horizontal rows, the sign changes to the opposite for intensive active alignment. Current leveling with significant pulses of weak charge in horizontal rows;
[symbol] Pulses at the output of comparator 405(K)

From the first oscillogram it can be seen that the magnitude of the amplitude of positive pulses decreases to a value below the response threshold set on the comparator. After that, the device switches to intensive active leveling mode with weak charge. This happens when there is an imbalance in voltage over time relative to the average value in horizontal rows.

An intensive active balancing of only current overcharging in the vertical rows of block 101 (BA) occurs. And after the overcharge voltage has been reduced, the device switches to intensive active leveling mode. After the voltage in the horizontal rows has fallen below the response threshold set on the comparator. In accordance with the current of a horizontal row of batteries that are weakly charged by voltage. This can be seen from the change in sign of the current leveling pulses in the vertical rows. In addition, when transitioning from one balancing mode to another, there is a certain pause in the supply of comparator pulses. The comparator pulses (FIGS. 5, 6, 7, 8) remain positive in all alignment modes.

### LIST OF REFERENCE NUMERALS

100 Battery pack (100) (Batteries)
101 Battery pack (101) (BA)
102 Switching unit of horizontal battery rows (102) (BKA)
103 Switching unit of current keys of vertical battery rows (103) (BKT)
110 Control unit for switching horizontal battery rows (110) (BUKA)
120 Control unit for switching control devices of current switches of vertical rows (120) (BUKT)
200 Consumption and charging system (200) (SDR)
300 Voltage measurement and balancing unit (300) (BIVN)
301 Rectifier (301) (B). Made according to the full-wave rectification scheme with one primary winding
302 Pulse matching amplifier (302) (DU)
Limiting resistor (R 301)
Voltage divider resistors (R302, R303)
400 Block for measuring and balancing current (400) (BIVT)
401 Rectifier (401) (B). Made according to the full-wave rectification scheme with two primary windings
402 Pulse matching amplifier (402) (US)
403 Single-position normally open key 403 (CI1)
404 Single-position normally open key (404) (KI2)
405 Pulse voltage inverting amplifier (405) (UI)
406 Comparator (406) (K)
407 Single-position normally open key (407) (KI3)
408 Voltage-controlled converter (408) (DC/DC)
409 Power supply for low-voltage electronics (409) (BPN),
410 Non-inverting pulse voltage amplifier (410) (UN)
411 Single-position normally open key (411) (KI4)
Limiting resistor (R 401)
500—Consumption current sensor (500) (DT)
600—Microcontroller (600) (MK)
700—Digital display unit (700) (BCI)
Common buses a and b for measuring the voltage of horizontal battery rows (101) (BA):
Common output of the horizontal row of the battery pack (101) (BA) with serial number h;
Common buses j and g measuring voltage proportional to the current of the vertical odd and even battery rows of block (101) (BA)
1,2,3, . . . n, n+1 controlled single-position closing switches with low internal resistance. Further in the text, keys with low internal resistance in horizontal rows;
1,2,3 . . . m−1, m controlled single-position closing switches with low internal resistance. Further in the text, keys with low internal resistance in vertical rows;
is the equivalent circuit of the battery. The circuit is represented as a series connection of a voltage source E and an internal resistance Ri

1. A monitoring device and method comprising a battery block (100) (battery bank) with a battery set (101) (BA) consisting of batteries connected in parallel series and having the following features:
each battery set has a resistor with small value R,
one output of the resistor is electrically connected to the positive terminal of its battery,
the second terminals of the resistors are combined into a common terminal and form n horizontal rows,
vertical rows of anodes of each previous battery are connected in series with the cathode of the next battery,
a battery switching unit (102) (BKA),
a battery switching control unit (110) (BUKA),
a consumption and charging system (200) (SPZ),
a voltage measurement and balancing unit (300) (BIVN),
a current sensor (500) (DT),
a microcontroller (600) (MK),
a digital display unit (700) (BCI),
a common bus a and b for measuring the voltage of the horizontal battery rows (101) (BA) as well as the common output of the horizontal battery row (101) (BA) with serial number h,
characterized in that
the battery pack (100) (Battery) is equipped with a switching unit for current switches

(103) (BKT) for vertical battery rows with a total of m,
a control unit for switching current switches of vertical rows (120) (BUKT), which is equipped with buses j and g for the outputs of current switches with odd and even serial numbers of unit (103) (BKT),
the measurement of voltage proportional to the current of the vertical battery rows (101) (BA) is carried out,
the voltage measurement and balancing unit (300) (BIVN) contains a rectifier (301) (V), a measurement and balancing unit (302) (BIV), a limiting resistor (R301), which is additionally equipped with a voltage divider, as well as two resistors (R301, R302),
the input of the voltage divider is connected to the rectifier (301) (V) and the midpoint of the voltage divider (R301, R302) is connected to the microcontroller (600) (MK).

2. Device according to claim 1, characterized by a current measurement and balancing unit (400) (BIVT), which contains a rectifier (401) (V), a pulse matching amplifier (402) (US), four single-stage closing switches (KI1, KI2, KI3, KI4), pulse inverting (405) (UI) and non-inverting (410) (UN) voltage amplifiers, comparator (406) (K), voltage-controlled converter (408) (DC/DC), low voltage electronics power supply (409) (BPN) and limiting resistor (R401).

3. Device according to claim 1, characterized in that the microcontroller additionally enables the control and balancing of currents in vertical rows, the control of a voltage-controlled converter depending on the energy and the maximum amplitude of the asymmetry voltage in the horizontal rows.

4. Unit for measuring and balancing voltage of asymmetry current in vertical rows as well as current consumption and charging systems, characterized in that the problem batteries determine the consumed differential power and display on a two-coordinate display of problem batteries based on electrical parameters.

5. Device according to claim 1 is characterized in that the digital display unit (700) (BCI) is additionally equipped with a raster two-coordinate screen, the number of pixels of which corresponds to the number of batteries in the battery block (101) (BA), whereby for displaying the relative change in current consumption of the batteries in the form of a luminance modulation of the amplitude of this parameter when polling horizontal and vertical battery rows is used.

6. Device according to claim 1 is characterized in that the resistors with small value R are structurally made of a material with high electrical resistance in the form of segments of a resistance band. One side of these bands is electrically welded to the jumpers of the vertical rows and they are structurally manufactured in the same configuration. The jumpers of the vertical rows are electrically connected to the poles of adjacent batteries of the vertical rows.

7. Device according to claim 1 is characterized in that the sections of the resistance band are on the other hand electrically connected by welding to a common electrical output of the horizontal row.

8. Method according to claim 1 differs in that for additional switching of current switches, the electrical voltage is sequentially switched from the anodes of the batteries of the n-th horizontal row of the battery pack with odd serial numbers from bus j to serial number bus g.

9. Method according to claim 7, characterized in that the control unit for switching the control devices of the current switches has vertical rows that sequentially supply the supply voltage to the control devices of the switching unit.

10. Method according to claim 7, characterized in that the current measurement and balancing unit performs simultaneous active current balancing in measurement mode during both overcharging and weak charging from a voltage-controlled converter via a limiting resistor.

11. Method according to one of claims 7 characterized in that the current measurement and leveling block switches to intensive active leveling mode and that for currents significantly over-and underestimated compared to the average value, an alternative comparison is performed at the comparator in intensive active balancing mode.

12. Method according to one of claims 7, characterized in that the unit for measuring and leveling the current in intensive active leveling mode of significant imbalance currents in vertical rows is supplied by a voltage-controlled microcontroller converter both during overcharging and undercharging.

13. Method according to one of claims 7, characterized in that the microcontroller (MC) controls the following:
currents in vertical rows,
a voltage-controlled converter depending on the energy level and the maximum amplitude of the asymmetry voltage in the horizontal rows of the voltage measurement and balancing unit,
the asymmetry current in vertical rows/columns and the current of the consumption and charging system,
and that the MC determines the differential power of batteries and determines an XY indication of batteries with problems based on their electrical parameters.

14. Method according to one of claims 7, characterized in that the digital display unit performs a digital display of the serial numbers of batteries with voltage and current problems in the device and that the block is additionally equipped with a bitmap with two coordinates, whereby the number of pixels corresponds to the number of accumulators in the block.

15. Method according to claim 7, characterized in that the transformation ratios of the converters of the voltage measurement and balancing units and the current measurement and balancing units are chosen by a numerical value.
